(19) United States
(12) Patent Application Publication
(10) Pub. No.: US 2026/0318970 A1
(43) Pub. Date: Oct. 15, 2026

(54) In-Vehicle Power Supply Network

(71) Applicant: Hitachi Astemo, Ltd., Hitachinaka-shi, Ibaraki (JP)

(72) Inventors: Nobuyasu KANEKAWA, Tokyo (JP); Hiroshi NAKANO, Tokyo (JP); Takao FUKUDA, Hitachinaka-shi (JP); Kentaro JUMONJI, Hitachinaka-shi (JP)

(21) Appl. No.: 19/108,469

(22) PCT Filed: Jul. 28, 2023
(86) PCT No.: PCT/JP2023/027758

§ 371 Date: Mar. 4, 2025

(30) Foreign Application Priority Data
Sep. 16, 2022 (JP) 2022-148161

(51) Int. Cl. G01R 31/00; B60R 16/03; G01R 1/20; G01R 1/30; G01R 19/00; G01R 31/08

(52) U.S. Cl. CPC G01R 31/006; B60R 16/03; G01R 1/203; G01R 1/30; G01R 19/0092; G01R 31/08

(57) ABSTRACT

An in-vehicle power supply network according to the present invention is an in-vehicle power supply network that supplies power to a load installed in a vehicle via a plurality of nodes in the vehicle, in which the plurality of nodes includes a first node that feeds power and a second node that receives the power fed out from the first node, the first and second nodes are connected by a power line over which the power is supplied and a signal line through which information relating the power is transmitted, each of the first and second nodes includes a current measurement unit that measures a current value entering and exiting the own node via the power line, a current input/output unit that inputs and outputs a current proportionate to the current value between the signal line and the own node, and a potential measurement unit that measures a potential of the signal line, the signal line is terminated at a terminal potential via a resistor, and when the potential of the signal line is different from the terminal potential, it is diagnosed that an abnormality has occurred somewhere in the in-vehicle power supply network.

### TECHNICAL FIELD

The present invention relates to power supply networks, and particularly to an in-vehicle power supply network suitable for an electrified vehicle.

### BACKGROUND ART

From the beginning of this century, electrification of auxiliary machines of automobiles such as electric power steering and electric brake has progressed. Furthermore, in recent years, electrification of main machines has also progressed as represented by a hybrid vehicle and an electric vehicle. In addition, automatic driving is also advanced, and in the future, even when a failure occurs in an automobile, the automobile itself is required to autonomously and automatically operate without human intervention. From the above background, there is a demand for higher performance and improvement in reliability (operation continuity at time of failure) of an in-vehicle power supply network that supports electrification and automation of automobiles.

In order to continue operation at time of failure of an in-vehicle power supply network having a daisy chain/ring topology configuration through multiple stages of electronic control units (zone ECUs) arranged in a vehicle body, it is necessary to detect in which section (between which zone ECUs) a failure has occurred, and to cut off and bypass the corresponding section. Note that “failure” in the present specification means a “power fault” in which the wiring is short-circuited to the power source, and a “ground fault” in which the wiring is short-circuited to the ground potential (GND).

In order to specify a section in which a failure has occurred, for example, PTL 1 discloses a differential current method for detecting whether a fed current and a received current match between a power feeding side and a receiving side in the section. According to this technology, when no fault has occurred in the section, the fed current and the received current match, but when a failure occurs, the fed current and the received current do not match, so that occurrence of a failure can be detected.

### CITATION LIST

### Patent Literature

PTL 1: JP 2021-90257 A

### SUMMARY OF INVENTION

### Technical Problem

However, in PTL 1, since the current is detected by the current transformer and the abnormality is determined by the relay, the application range thereof is limited to the alternating current which is the mainstream in the commercial power supply, and cannot be applied to the direct current which is the mainstream in the in-vehicle power supply network at present.

The present invention has been made in view of the above problems, and an object of the present invention is to provide an in-vehicle power supply network that uses a direct current and can quickly detect the occurrence of a failure.

### Solution to Problem

In order to achieve the above object, an in-vehicle power supply network according to the present invention is an in-vehicle power supply network that supplies power to a load installed in a vehicle via a plurality of nodes in the vehicle, in which the plurality of nodes includes a first node that feeds power and a second node that receives the power fed out from the first node, the first and second nodes are connected by a power line over which the power is supplied and a signal line through which information relating the power is transmitted, each of the first and second nodes includes a current measurement unit that measures a current value entering and exiting the own node via the power line, a current input/output unit that inputs and outputs a current proportionate to the current value between the signal line and the own node, and a potential measurement unit that measures a potential of the signal line, the signal line is terminated at a terminal potential via a resistor, and when the potential of the signal line is different from the terminal potential, diagnosis is made that an abnormality has occurred somewhere in the in-vehicle power supply network.

### Advantageous Effects of Invention

According to the present invention, occurrence of a failure can be quickly detected in an in-vehicle power supply network using a direct current.

Further features related to the present invention will become apparent from the description of the present specification and the accompanying drawings. Furthermore, problems, configurations, and effects other than those described above will be clarified by the following description of examples.

### BRIEF DESCRIPTION OF DRAWINGS

FIG. 1 is a diagram illustrating a basic configuration of an in-vehicle power supply network according to a first example of the present invention.

FIG. 2 is a diagram illustrating an example of a temporal elapse of diagnosis executed from the occurrence of a failure in the in-vehicle power supply network until the specification of a failure part.

FIG. 3 is a graph illustrating a relationship between a type of failure that has occurred and a potential of a sensing line.

FIG. 4 is a diagram illustrating a configuration of an in-vehicle power supply network according to a second example in which a termination is a Thevenin termination.

FIG. 5 is a diagram illustrating a configuration in which the Thevenin termination is built in an ECU 200-1.

FIG. 6 is a diagram illustrating a configuration in which the Thevenin termination is built in an ECU 200-2.

FIG. 7 is a diagram illustrating a configuration of an in-vehicle power supply network according to a third example in which network communication in the in-vehicle power supply network is multiplexed.

FIG. 8 is a graph illustrating a change in potential in a case where a potential is transmitted at a Recessive voltage of a CAN.

FIG. 9 is a diagram illustrating an example of a configuration adopted in a case where a potential is transmitted at the Recessive voltage of the CAN.

FIG. 10 is a diagram illustrating a configuration of an in-vehicle power supply network according to a fourth example in which an ECU 200-3 is added by branching a power line.

FIG. 11 is a diagram illustrating a configuration of an in-vehicle power supply network according to a fifth example, illustrating a detailed configuration of a current measurement unit and a current input/output unit.

FIG. 12 is a diagram illustrating a configuration in which a current amplifier circuit is added to the configuration of FIG. 11.

FIG. 13 is a diagram illustrating a configuration of an in-vehicle power supply network according to a sixth example in which power supply is redundant power supply.

FIG. 14 is a diagram illustrating a modified example of the in-vehicle power supply network according to the sixth example.

FIG. 15 is a diagram illustrating another modified example of the in-vehicle power supply network according to the sixth example.

FIG. 16 is a diagram illustrating a configuration of an in-vehicle power supply network according to a seventh example applied to four ECUs installed in an automobile.

FIG. 17 is a table illustrating a relationship between a part where a failure has occurred and an open/close state of a switch in the configuration of FIG. 16.

FIG. 18 is a modified example of the in-vehicle power supply network according to the seventh example.

FIG. 19 is a diagram illustrating a configuration of an in-vehicle power supply network according to an eighth example applied to four ECUs installed in an automobile.

FIG. 20 is a table illustrating a relationship between a part where a failure has occurred and an open/close state of a switch in the configuration of FIG. 19.

FIG. 21 is a modified example of the in-vehicle power supply network according to the eighth example.

FIG. 22 is a diagram illustrating a type of a switch made of a semiconductor.

### DESCRIPTION OF EMBODIMENTS

Hereinafter, examples of the present invention will be described with reference to the drawings.

### First Example

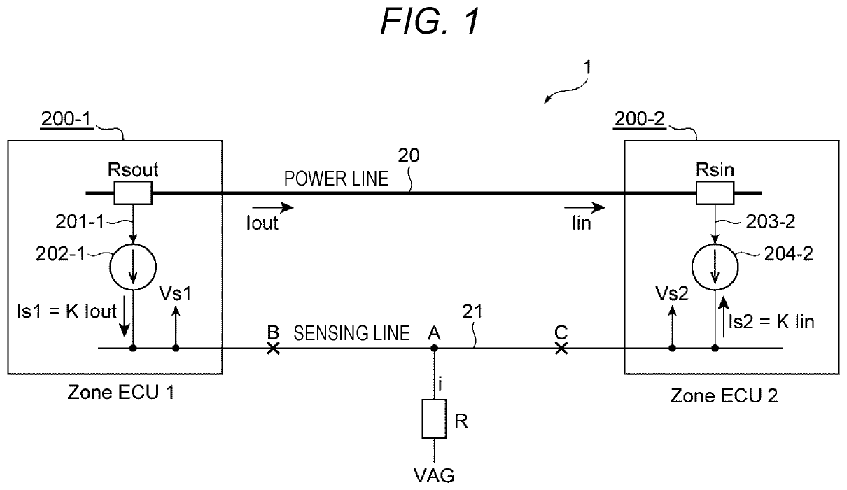

FIG. 1 is a diagram illustrating a basic configuration of an in-vehicle power supply network according to a first example of the present invention.

An in-vehicle power supply network 1 according to the first example supplies power from a power source (not illustrated) to a load (not illustrated) installed in a vehicle via a plurality of ECUs. The in-vehicle power supply network 1 includes an ECU 200-1 that feeds power and an ECU 200-2 that receives power fed out from the ECU 200-1. The ECU 200-1 and the ECU 200-2 are connected by a power line 20 over which power is supplied and a sensing line 21 through which information on power is transmitted.

The ECU 200-1 includes a current measurement unit 201-1 that measures a current Iout fed via the power line 20, and a current input/output unit 202-1 that causes a current Is1=K×Iout proportionate to the measured current Iout to flow through the sensing line 21. Here, K is a predetermined proportional constant. Similarly, the ECU 200-2 includes a current measurement unit 203-2 that measures the current Iin received via the power line 20, and a current input unit 204-2 that receives the current Is2=K×Iin proportionate to the current Iin from the sensing line 21. Note that in FIG. 1, the current flows from the ECU 200-1 to the ECU 200-2, but alternatively, the current may flow from the ECU 200-2 to the ECU 200-1. In this case, the current flowing through the sensing line 21 is output from the current input unit 204-2 of the ECU 200-2 and input to the current input/output unit 202-1 of the ECU 200-1. Therefore, hereinafter, these are not distinguished, and are collectively referred to as a current input/output unit.

Furthermore, the sensing line 21 is terminated to the potential VAG via the resistor R. In addition, a potential measuring device capable of measuring a potential at an arbitrary position, and a central processing unit (CPU) for controlling operations of a voltage source, an ECU, and a potential measuring device are connected to the power supply network 1 (none are illustrated).

Here, assuming that the potential of the sensing line 21 is Vs and the current flowing via the resistor R is i,

$$i = ( VAG - Vs ) / R \qquad ( 1 )$$

From formula (1)

$$Vs = VAG - R \times i \qquad ( 2 )$$

According to Kirchhoff's law of current at point A,

$$i + K \times Iout - K \times Iin = 0 \qquad ( 3 )$$

From formula (3)

$$i = K \times Iin - K \times Iout \qquad ( 4 )$$

Substituting formula (4) into formula (2),

$$Vs = VAG - R \times K ( Iin - Iout ) \qquad ( 5 )$$

is obtained.

From Formula (5), it can be seen that the potential Vs of the sensing line 21 includes information on the difference (Iin−Iout) between the received current and the fed current, and when both are equal, that is, Iin=Iout, Vs=VAG is satisfied.

Note that, here, the value of K is set such that the values of Is1 and Is2 fall within a range appropriate for information sharing with respect to Iin and Iout to be actually targeted. For example, when K=10⁻³, the values of Is1 and Is2 are in a range of several mA with respect to Iin and Iout of several A, when K=10⁻⁴, the values of Is1 and Is2 are in a range of several mA with respect to Iin and Iout of several ten A, and when K=10⁻⁵, the values of Is1 and Is2 are in a range of several mA with respect to Iin and Iout of several hundred A, which ranges are such that there is no problem of noise generation due to Is1 and Is2. The values of VAG and R are set so that the value of Vs is in a range convenient for measurement. For example, in a case where measurement is performed with a circuit in which the positive power supply voltage Vcc of the entire circuit is 5 V, it is preferable that VAG=Vcc/2=about 2.5 [V].

At this time,

$$VAG = Vcc / 2 \qquad ( 6 )$$

Substituting Formula (6) into Formula (5),

$$Vs = ( Vcc / 2 ) - R \times K ( Iin - Iout ) \qquad {( 5 )}^{′}$$

is obtained.

At this time, when R=10³, a voltage range of Vs=(Vcc/2)±several V is obtained with respect to a current difference (Iin−Iout) of several A.

Note that, as described above, also in a case where the current flows in the direction from the ECU 200-2 to the ECU 200-1 contrary to the configuration of FIG. 1, the above operation is established only by reversing the directions (signs) of Iout and Iin.

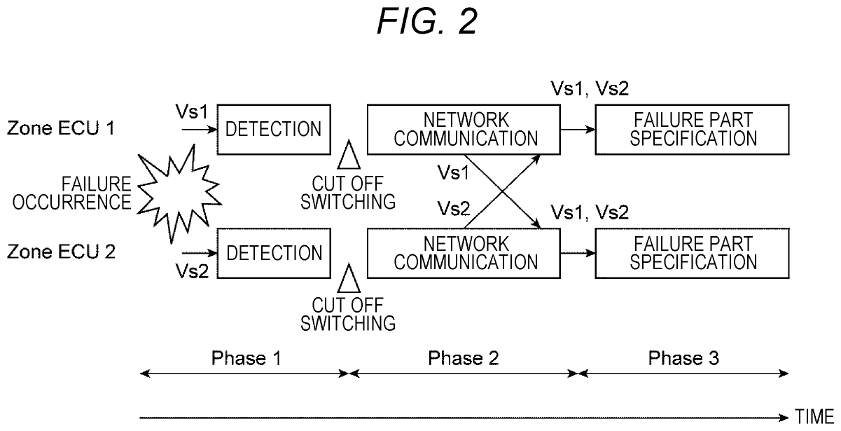

FIG. 2 is a diagram illustrating an example of a temporal elapse of diagnosis executed from the occurrence of a failure in the in-vehicle power supply network until the specification of a failure part. Specifically, a flow of failure occurrence→failure detection→cutoff switching→network communication→failure part specification is illustrated. First, in Phase 1, the occurrence of failure is detected as abnormality of the potentials Vs1 and Vs2 of the sensing lines 21 connected to the ECU 200-1 and the ECU 200-2. Then, the power line 20 is cutoff switched to prevent and protect the power line 20 and circuits in the ECU 200-1 and the ECU 200-2 from heat generation, destruction, and ignition due to overcurrent. Subsequently, in Phase 2, the potentials Vs1 and Vs2 of the sensing lines 21 respectively measured by the ECU 200-1 and the ECU 200-2 are exchanged by network communication. By sharing the potentials Vs1 and Vs2 of the sensing lines 21 detected by both sides in this manner, it becomes possible to specify a failure part in Phase 3 as described below.

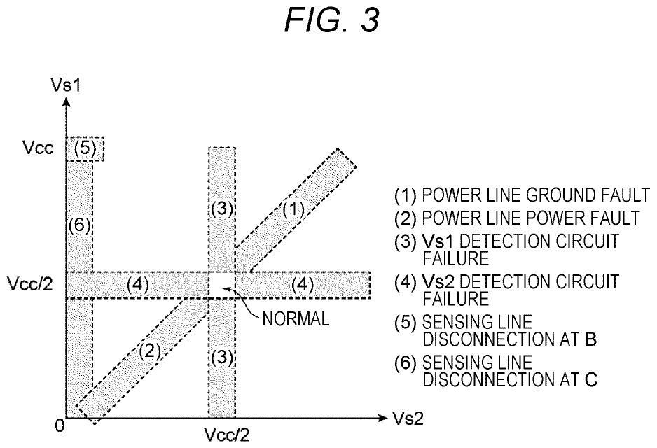

FIG. 3 is a graph illustrating a relationship between a type of failure that has occurred and a potential of a sensing line used for diagnosis for specifying a failure part in Phase 3. The vertical axis represents the potential Vs1 of the sensing line 21 measured by the ECU 200-1, and the horizontal axis represents the potential Vs2 of the sensing line 21 measured by the ECU 200-2. In a case where no failure has occurred in the in-vehicle power supply network 1 and all are normal, both Vs1 and Vs2 take values substantially equal to VAG (=Vcc/2).

In the case of the power line ground fault, since the impedance of the entire system decreases, the current flowing into the sensing line 21 increases. Therefore, both Vs1 and Vs2 take values in the region (1) larger than Vcc/2. In the case of the power line power fault, since the impedance of the entire system increases conversely, the current flowing into the sensing line 21 decreases. Therefore, both Vs1 and Vs2 take values smaller than Vcc/2 of the region (2).

When the Vs1 detection circuit of ECU 200-1 fails, Vs2 in region (3) takes a value substantially equal to Vcc/2, and Vs1 takes a value different from Vcc/2. When the Vs2 detection circuit of ECU 200-2 fails, Vs1 in region (4) takes a value substantially equal to Vcc/2, and Vs2 takes a value different from Vcc/2.

In a case where the sensing line is disconnected at a position on the ECU 200-1 side with respect to the position where the potential VAG is connected to the sensing line 21, for example, at a point B in FIG. 1, Vs1 is not terminated by the resistor R and thus can be thrown off to Vcc by Is1, and Vs2 is terminated by the resistor R and thus is 0 V in a case where the current input/output unit 204-2 is driven by one-side power supply (Vcc to 0 V), and −Is2×R in proportion to Is2 in a case where the current input/output unit is driven by both power supplies (Vcc to −Vcc) (region (5)). In a case where the sensing line is disconnected at a position on the ECU 200-2 side with respect to the position where the potential VAG is connected to the sensing line 21, for example, at a point C in FIG. 1, Vs1 is terminated by the resistor R and thus is Is1×R in proportion to Is1, and Vs2 is not terminated by the resistor R and thus is 0 V in a case where the current input/output unit 204-2 is driven by one-side power supply (Vcc to 0 V), and −Vcc in a case where the current input/output unit is driven by both power supplies (Vcc to −Vcc) (region (6)).

According to the principle described above, the part where the failure has occurred in the in-vehicle power supply network 1 using the direct current can be quickly specified, and the entire system can be protected by cutting off so as to bypass the failure part by merely measuring the potential of the sensing line 21 connected between the ECU 200-1 and the ECU 200-2.

### Second Example

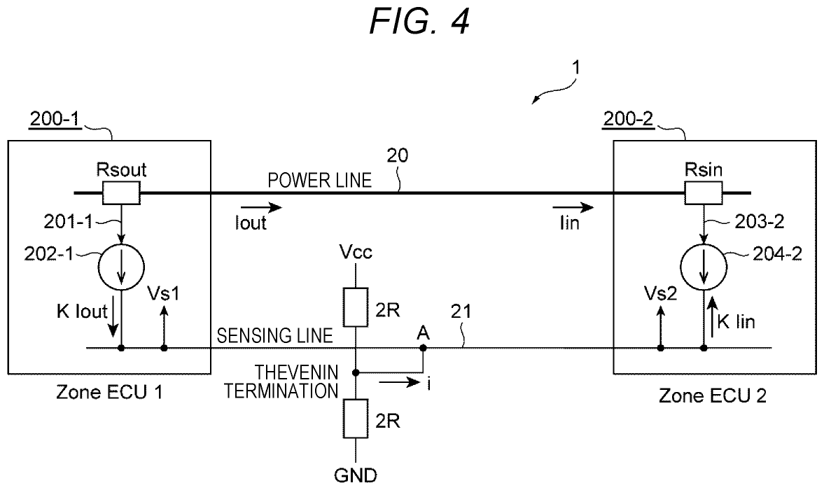

FIG. 4 is a diagram illustrating a configuration of an in-vehicle power supply network 1 according to a second example. The in-vehicle power supply network 1 according to the present example is different from the in-vehicle power supply network 1 according to the first example in that a termination of the sensing line 21 is a Thevenin termination. In the present example, the sensing line 21 is terminated at the resistor 2R to the ground potential GND and the positive power supply voltage Vcc, so that a circuit equivalent to a circuit terminated at the resistor R to the potential Vcc/2 according to the Thevenin theorem is obtained. According to the present example, unlike the first example, it is not necessary to provide a power supply (voltage source) for the terminal potential VAG=Vcc/2 separately from the positive power supply voltage Vcc, and hence the circuit configuration can be further simplified.

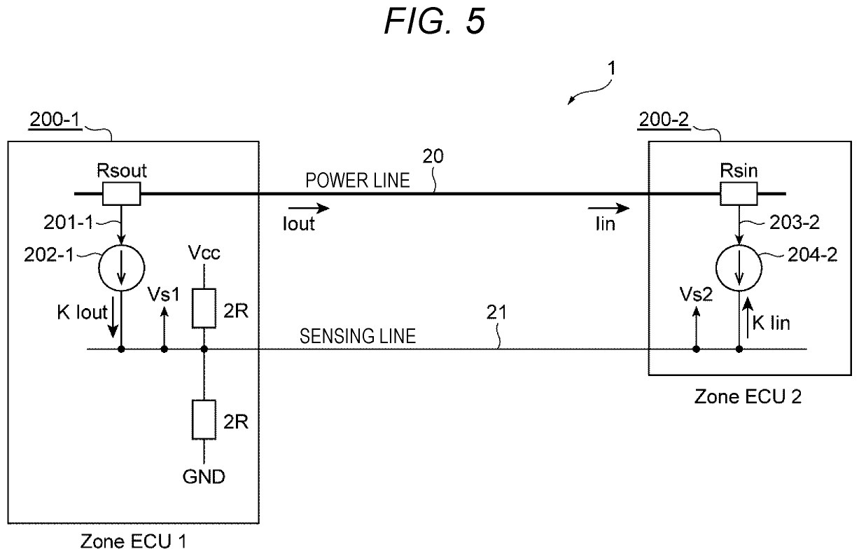

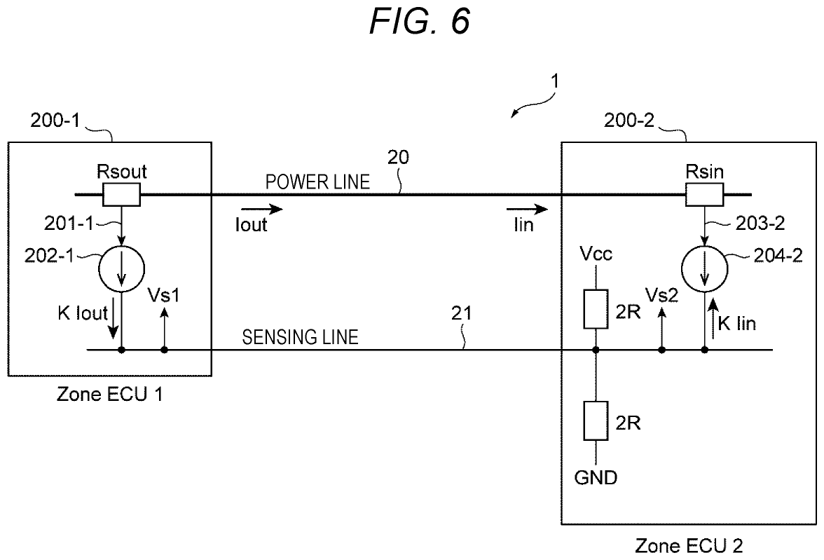

Note that in FIG. 4, the Thevenin resistor is provided in the sensing line 21 between the ECU 200-1 and the ECU 200-2, but as illustrated in FIGS. 5 and 6, the termination portion may be built in either the ECU 200-1 or the ECU 200-2. FIG. 5 illustrates an example in which a termination portion is built in the ECU 200-1, and FIG. 6 illustrates an example in which a termination portion is built in the ECU 200-2.

### Third Example

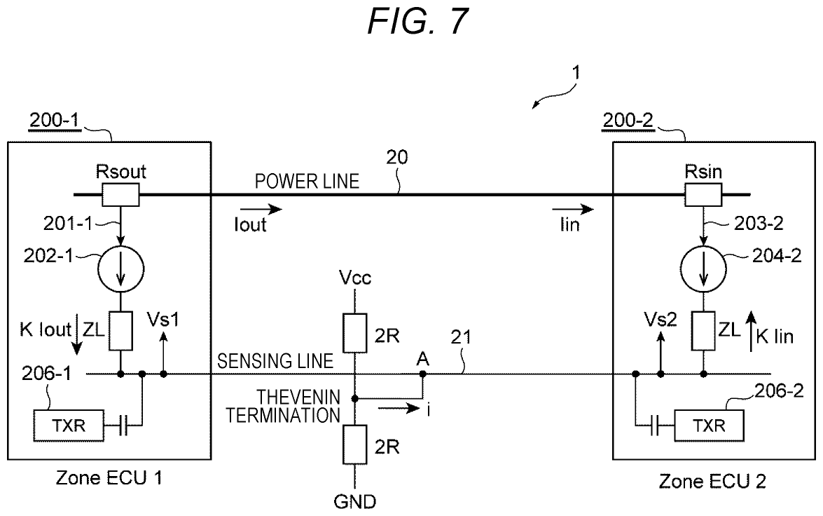

FIG. 7 is a diagram illustrating a configuration of an in-vehicle power supply network 1 according to a third example in which internal network communication is multiplexed. In the in-vehicle power supply network 1 according to the present example, network transceivers 206-1 and 206-2 are built in the ECU 200-1 and the ECU 200-2, respectively. These network transceivers 206-1 and 206-2 can be used as communication lines for sharing Vs1 and Vs2 between the ECU 200-1 and the ECU 200-2 in Phase 2 described in FIG. 2.

Examples of a method of bidirectional communication for sharing Vs1 and Vs2 include the following methods.

### Baseband Transmission:

TDMA (Time Division Multiple Access)

### Modulated Wave Transmission:

TDMA (Time Division Multiple Access)
FDMA (Frequency Division Multiple Access)
CDMA (Code Division Multiple Access)

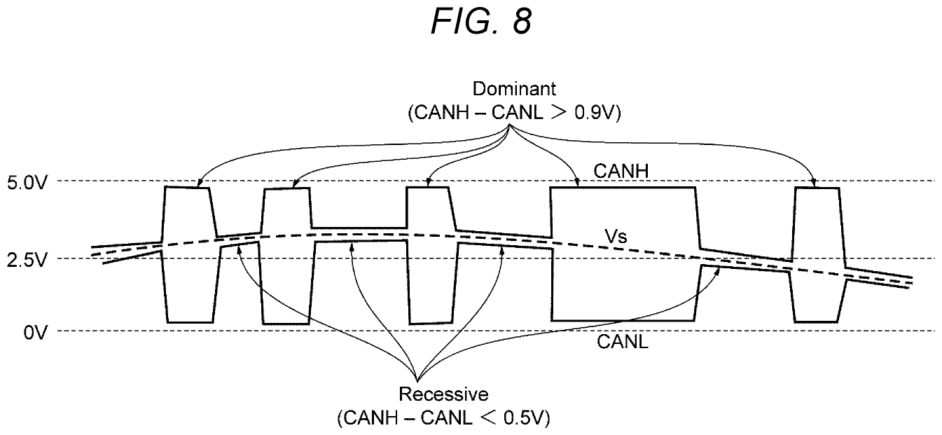

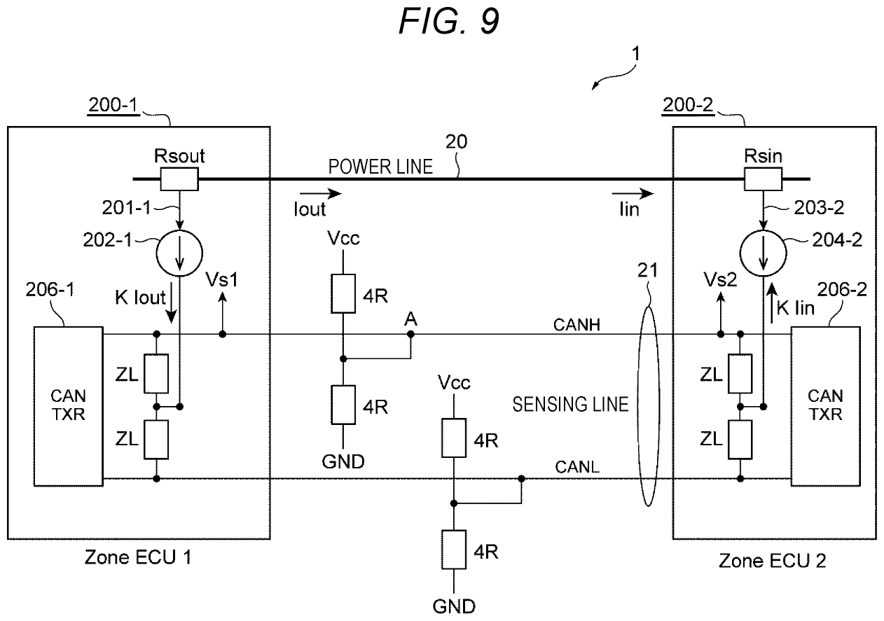

FIGS. 8 and 9 are diagrams illustrating a potential change and configuration in a case where a control area network (CAN) is used for network communication using the sensing line 21 using the network transceivers 206-1 and 206-2 and the potential Vs is transmitted as a voltage at the time of Recessive. The voltage at the time of Recessive of the CAN is usually about 2.5 V, but when the voltage at the time of Recessive is set to Vs, Vs can be shared as Vs1 and Vs2 by the ECU 200-1 and the ECU 200-2 connected to the sensing line 21.

In FIG. 9, at the time of Dominant, the transistor connected to Vcc is turned ON for the CANH terminals of the CAN transceivers 206-1 and 206-2, and the transistor connected to GND is turned ON for the CANL terminals. In addition, at the time of Recessive, the transistor connected to Vcc is turned OFF for the CANH terminals of the CAN transceivers 206-1 and 206-2, and the transistor connected to GND is turned OFF and the voltage normally becomes about 2.5 V for the CANL terminals. However, the potential becomes Vs according to Formula (5)′ by the current Is1 from the current input/output unit 202-1, the current Is2 from the current input/output unit 204-2, and the termination resistor.

In this case, as illustrated in FIG. 8, since the differential voltage is less than 0.5 V at the time of Recessive and the differential voltage exceeds 0.9 V at the time of Dominant, Vs can be transmitted without affecting the communication itself of the CAN.

According to the present example, detection→cutoff switching of Phase 1 in FIG. 2 is performed by the voltage Vs at the time of Recessive in each of the ECU 200-1 and the ECU 200-2, and the CAN can be used for network communication of Phase 2 to failure part specification of Phase 3.

### Fourth Example

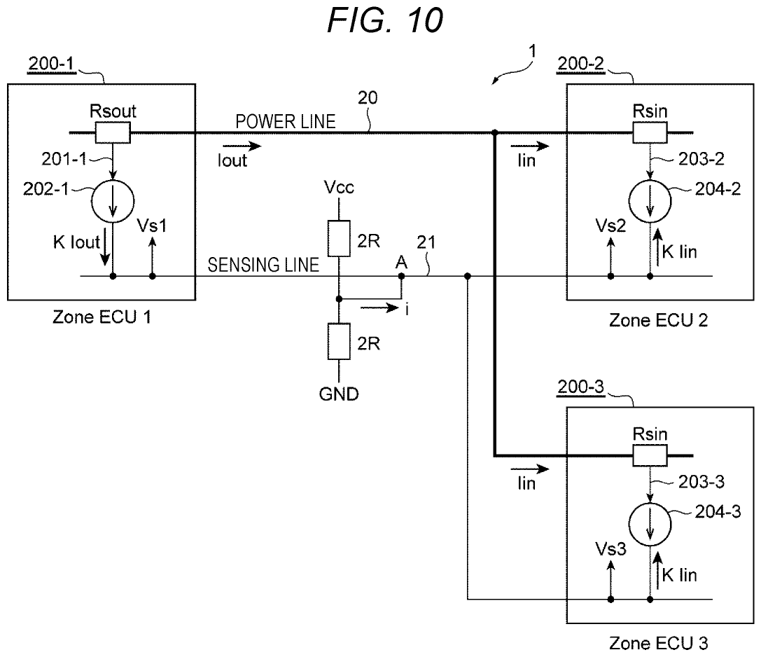

FIG. 10 is a diagram illustrating a configuration of an in-vehicle power supply network according to a fourth example in which the power line 20 is branched and an ECU 200-3 is added. Kirchhoff's law for currents flowing in and out of the ECU 200-1, the ECU 200-2, and the ECU 200-3 via the sensing line 21 having the same topology as the power line 20 is established in a similar manner to Kirchhoff's law for currents flowing in and out of the ECU 200-1, the ECU 200-2, and the ECU 200-3 via the power line 20, and thus the operation described in the first example is similarly established even in the case of being branched as in the present example. Furthermore, in the present example, the case where the power line 20 is branched into two lines is shown, but regardless of the number of lines the power line is branched into, Kirchhoff's law for the currents flowing in and out from the plurality of ECUs through the sensing line 21 having the same topology as the power line 20 is established similarly to Kirchhoff's law for the currents flowing in and out from the plurality of ECUs through the power line 20, and thus the operation illustrated in the first example is similarly established.

### Fifth Example

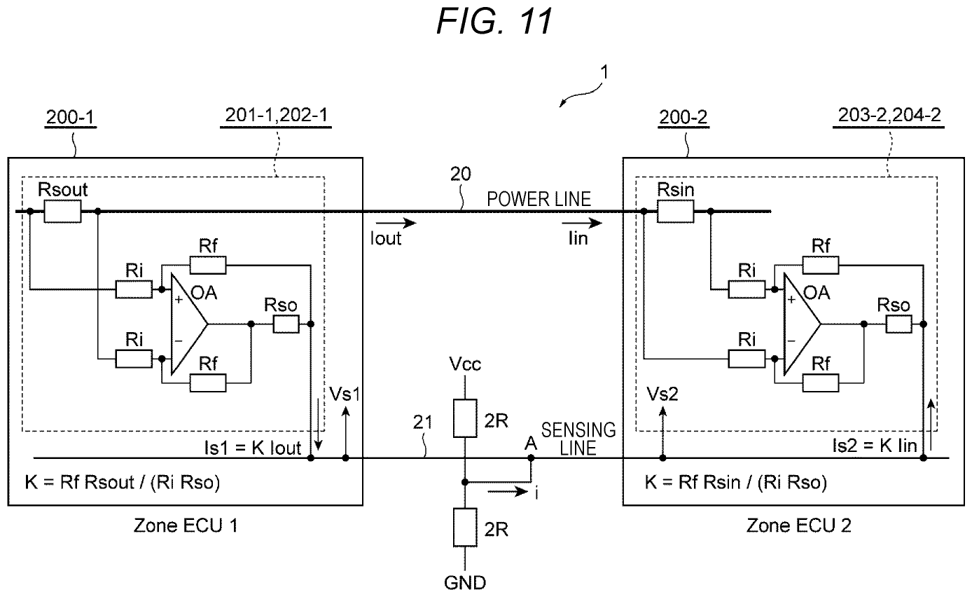

FIG. 11 is a diagram illustrating a configuration of an in-vehicle power supply network according to a fifth example, illustrating detailed configurations of current measurement units 201-1 and 203-2 and current input/output units 202-1 and 204-2.

In the current measurement unit 201-1 and the current input/output unit 202-1, the current Iout output from the ECU 200-1 is measured by the shunt resistor Rsout. At this time, the voltage difference between both ends of the shunt resistor Rsout is Iout×Rsout. The voltages at both ends of the shunt resistor Rsout are connected to the + input terminal and the − input terminal of an operational amplifier OA via the input resistor Ri, respectively. The output of the operational amplifier OA is output to the sensing line 21 via another shunt resistor Rso. Here, the shunt resistor Rso is provided to measure the output current from the operational amplifier OA, and the voltage difference between both ends of the shunt resistor Rso is Is1×Rso. The voltages at both ends of the shunt resistor Rso are connected to the + input terminal and the − input terminal of the operational amplifier OA via a feedback resistor Rf, respectively. Here, considering a potential difference [(Vin+)−(Vin−)] between the + input terminal and the − input terminal of the operational amplifier OA,

$$( Vin + ) - ( Vin - ) = ( Rf \times Iout \times Rsout - Ri \times Is 1 \times Rso ) / ( Rf + Ri ) \qquad ( 7 )$$

is obtained.

Here, since the gain of the operational amplifier OA is ideally infinite, a voltage is output from the output terminal so that (Vin+)−(Vin−)→0 is satisfied. Therefore, if the left side of Formula (7)=0,

$$Is 1 = Rf \times Iout \times Rsout / Ri \times Rso \qquad ( 8 )$$

$$K = Is 1 / Iout = Rf \times Rsout / ( Ri \times Rso ) \qquad ( 9 )$$

are obtained.

The same applies to the current measurement unit 203-2 and the current input/output unit 204-2 on the ECU 200-2 side, and

$$K = Is 2 / Iin = Rf \times R sin / ( Ri \times Rso ) \qquad ( 10 )$$

is obtained.

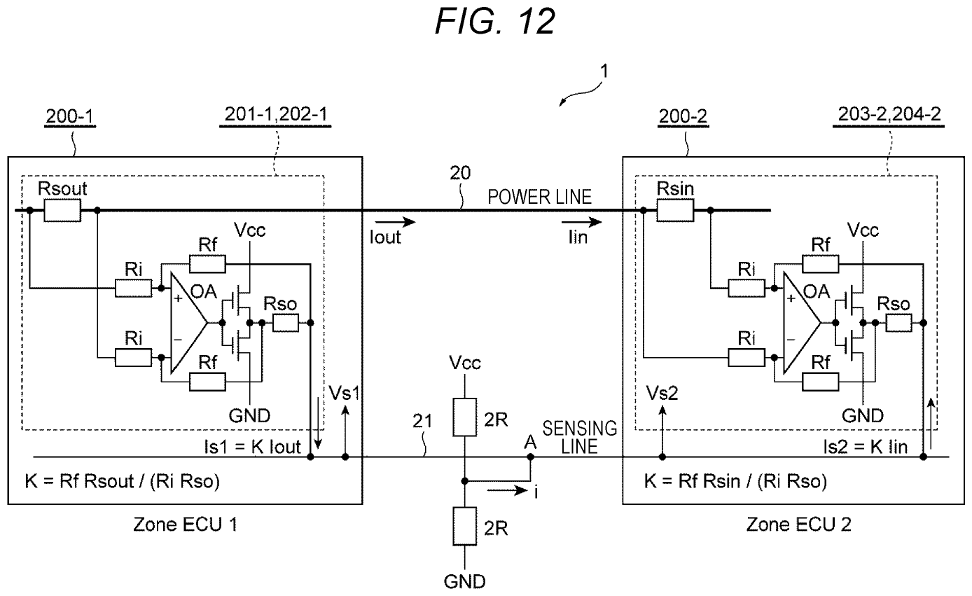

FIG. 12 illustrates an example in which a current amplifier circuit is added to the subsequent stage of the operational amplifier OA in addition to the configuration illustrated in FIG. 11. The output current of the operational amplifier OA is usually about 25 mA, but by adding a current amplifier circuit, a current exceeding the output current can be output to the sensing line 21. Even in this case, the output currents Is1 and Is2 are measured by the shunt resistor Rso and fed back to the operational amplifier OA, so that the operation as shown in Formulas (7) to (10) is performed.

### Sixth Example

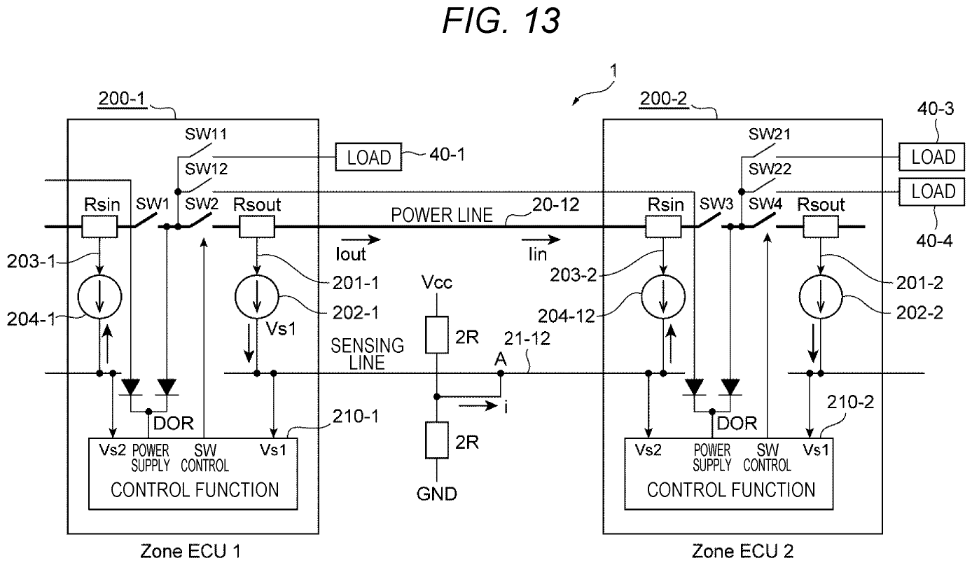

FIG. 13 illustrates an example of the ECUs 200-1 and 200-2 for implementing the present invention. The ECU 200-1 is connected, through the power line 20, to another ECU 200-2 via the switches SW 1 and SW 2, and is further connected to a load 40-1 via a switch SW 11. In addition, it is also connected to a control function 210-2 of another ECU 200-2 via a switch SW 12. The control function 210-1 controls the switches SW 1, SW 2, SW 11, and SW 12 based on the potentials Vs1 and Vs2 of the sensing lines. Power is supplied to the control function 210-1 from a connection point of the switches SW 1 and SW 2 and an external power supply via a diode OR (DOR). With the power supply configuration as described above, even when the switches SW 1 and SW 2 are cut off at the time of failure, power is supplied from the external power supply, so that the control of the switches SW 1, SW 2, SW 11, and SW 12 can be continued.

Similarly, the ECU 200-2 is connected, through the power line 20, to other ECUs via the switches SW 3 and SW 4, and is further connected to loads 40-3 and 40-4 via switches SW 21 and SW 22. The control function 210-2 controls the switches SW 3, SW 4, SW 21, and SW 22 based on the potentials Vs1 and Vs2 of the sensing lines. Power is supplied to the control function 210-2 from a connection point of the switches SW 3 and SW 4 and an external power supply (ECU 200-1) via a diode OR (DOR). With the power supply configuration as described above, even when the switches SW 3 and SW 4 are cut off at the time of failure, power is supplied from the external power supply (ECU 200-1), so that the control of the switches SW 3, SW 4, SW 21, and SW 22 can be continued.

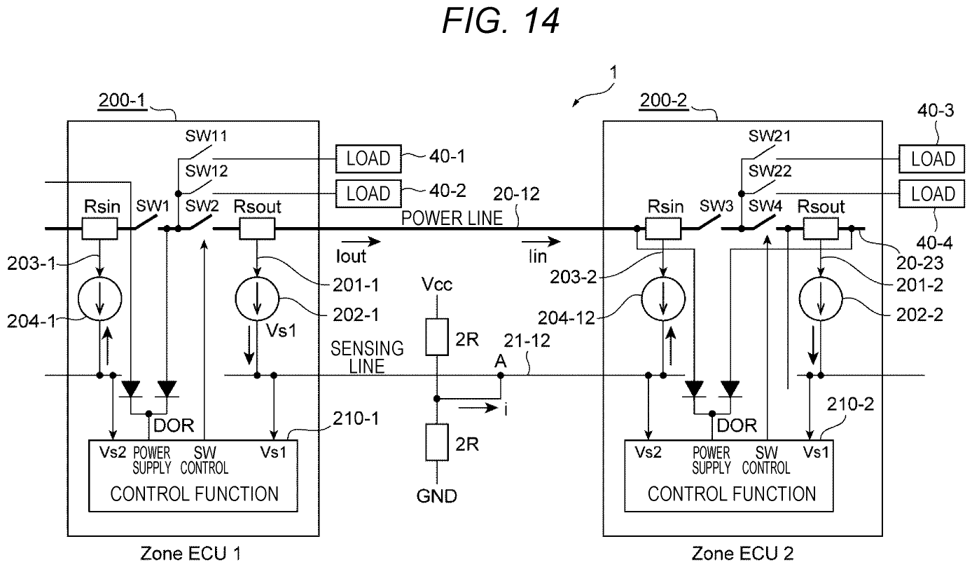

FIG. 14 illustrates an example in which power is supplied to the control function 210-2 in the ECU 200-2 from a power line 20-12 connected to the ECU 200-1 and a power line 20-23 connected to another power supply via a diode OR (DOR). With the power supply configuration as described above, even when the switches SW 3 and SW 4 are cut off at the time of failure, power is supplied from the power line 20-12 or the power line 20-23, so that the control of the switches SW 3, SW 4, SW 21, and SW 22 can be continued.

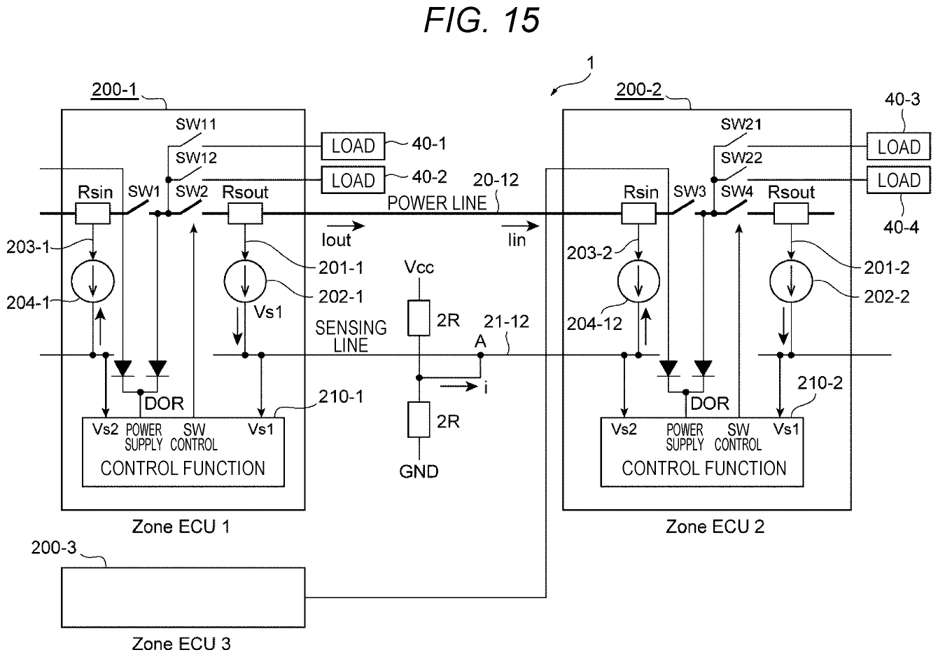

FIG. 15 illustrates an example in which power is supplied to the control function 210-2 in the ECU 200-2 from a connection point of the switches SW 3 and SW 4 and an external power supply (ECU200-3) via a diode OR (DOR). With the power supply configuration as described above, even when the switches SW 3 and SW 4 are cut off at the time of failure, power is supplied from the external power supply (ECU 200-3) of a different system from the ECU 200-1 over which power is supplied via the SW 3, so that the control of the switches SW 3, SW 4, SW 21, and SW 22 can be continued.

### Seventh Example

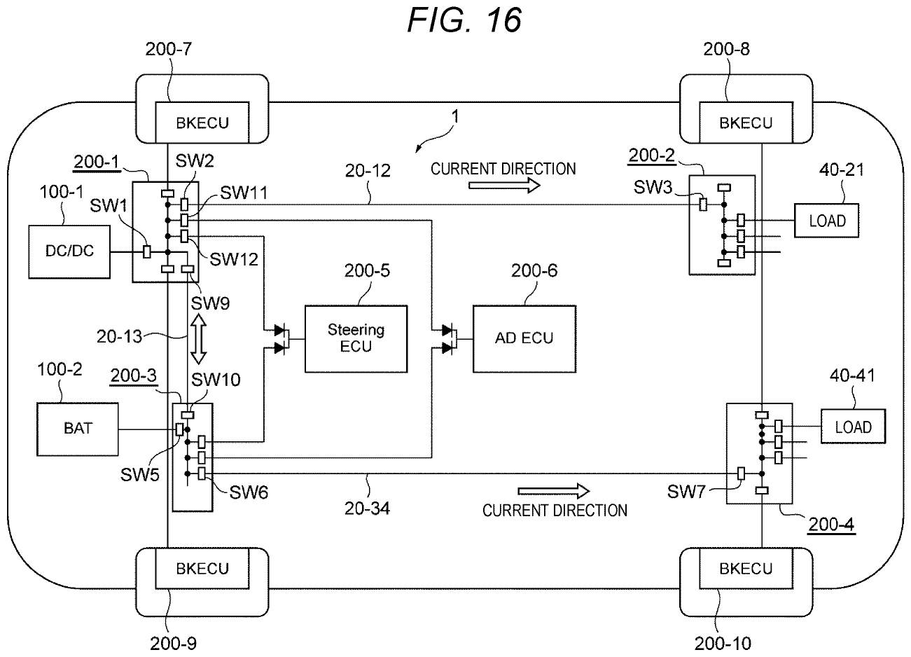

FIGS. 16 to 22 illustrate examples for a case in which the above-described power supply network is installed in a vehicle.

FIG. 16 illustrates an example in which power is supplied from the power source 100-1 to the ECU 200-1, power is supplied from the power source 100-2 to the ECU 200-3, the ECU 200-1 and the ECU 200-3 are connected via the power line 20-13, power is further supplied from the ECU 200-1 to the ECU 200-2 via the power line 20-12, and power is further supplied from the ECU200-3 to the ECU200-4 via the power line 20-34. Note that, in order to simplify the description, only components that particularly need to be described are denoted by reference numerals.

The ECU 200-1 is supplied with power from the power source 100-1 via the switch SW 1, the ECU 200-2 is supplied with power via the switch SW 2 and the power line 20-12, and the ECU 200-3 is connected via the SW 9 and the power line 20-13. The ECU 200-2 is supplied with power from the ECU 200-1 via the switch SW 3.

The ECU 200-3 is supplied with power from the power source 100-2 via the switch SW 5, the ECU200-4 is supplied with power via the switch SW 5 and the power line 20-34, and the ECU 200-1 is connected via the SW 10 and the power line 20-13. The ECU 200-4 is supplied with power from the ECU 200-3 via the switch SW 7.

Note that sensing lines (not illustrated) that are signal lines for sharing current information are provided in the power lines 20-12, 20-13, and 20-34, respectively, and a failure in the power lines 20-12, 20-13, and 20-34 is detected by the method provided by the present invention.

The power source 100-1 is a DC/DC converter, and is connected to a main machine driving battery (not illustrated) and a main machine (motor/generator). In a case where the vehicle is a hybrid car, the main machine is mechanically connected to the engine, and in a case where the vehicle is an electric car, the main machine driving battery is connected to a charger or a connection terminal with the charger. Normally, regenerative power from the main machine driving battery or the main machine (motor/generator) is converted into an auxiliary machine driving voltage by the DC/DC converter of the power source 100-1 and supplied to the ECU 200-1.

The power source 100-2 is an auxiliary machine driving battery, and is normally subjected to floating charge by the output of the power source 100-1 via the ECU 200-1 and the ECU 200-3.

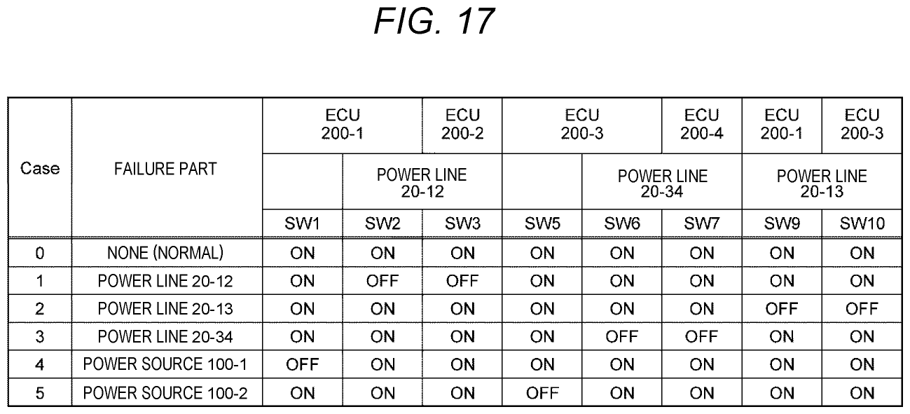

The operation of each switch in the present example is illustrated in FIG. 17. In Case 0, when there is no failure part (normal), all the switches are turned ON, and power is supplied to all the loads. Note that power is supplied to the steering ECU 200-5 and the automatic driving ECU 200-6 via the diode OR, and power is also supplied to the electric brake ECUs (BK ECUs) 200-7 to 200-10 via the respective switches.

Case 1 is a case where a failure occurs in the power line 20-12. The failure is detected according to the principle of the present invention described with reference to FIGS. 1 to 3, and the switches SW 2 and SW 3 are turned OFF and the power line 20-12 is disconnected. At this time, the power supply to the ECU 200-2 is cut off, and the power supply to the load 40-21 is also cut off.

Case 2 is a case where a failure occurs in the power line 20-13. The failure is detected according to the principle of the present invention, and the switches SW 9 and SW 10 are turned OFF and the power line 20-13 is disconnected. At this time, the battery that is the power source 100-2 is cut off from the power source 100-1, and thus floating charge is not performed.

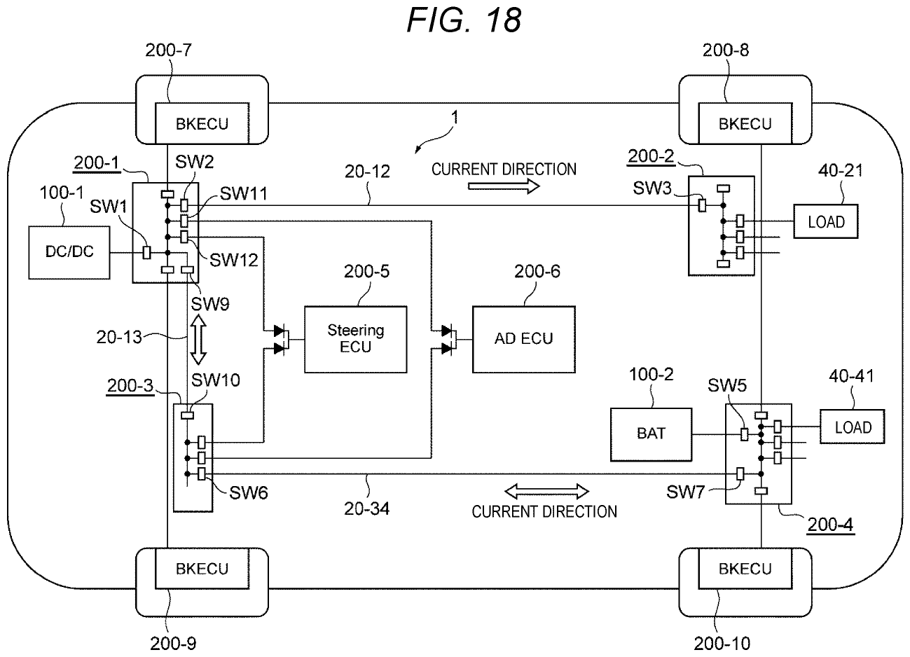

Case 3 is a case where a failure occurs in the power line 20-34. The failure is detected according to the principle of the present invention, and the switches SW 6 and SW 7 are turned OFF and the power line 20-34 is disconnected. At this time, the power supply to the ECU 200-4 is cut off, and the power supply to the load 40-41 and the electric brake ECUs (BK ECUs) 200-8 and 200-10 of the rear wheels is cut off. At this time, as illustrated in FIG. 18, by connecting a battery that is the power source 100-2 to the ECU 200-4, even when a failure occurs in the power line 20-34, power supply to the ECU 200-4, the load 40-41, and the electric brake ECUs (BK ECUs) 200-8 and 200-10 of the rear wheels is continued. Note that, since an important load is usually concentrated on the front side of the vehicle body in many cases, it is desirable to connect a battery that is the power source 100-2 to the ECU 200-3 as illustrated in FIG. 16.

Case 4 is a case where a failure occurs in the power source 100-1. The failure is detected by monitoring the output of the power source 100-1 or a self-diagnosis function of the power source 100-1, and the switch SW 1 is turned OFF and the power source 100-1 is disconnected. At this time, power is supplied to the entire in-vehicle power supply network by the output of the power source 100-2 subjected to floating charge.

Case 5 is a case where a failure occurs in the power source 100-2. The failure is detected by monitoring the output of the power source 100-2 or a self-diagnosis function of the power source 100-2, and the switch SW 5 is turned OFF and the power source 100-2 is disconnected. At this time, power is supplied to the entire in-vehicle power supply network by the output of the power source 100-1.

### Eighth Example

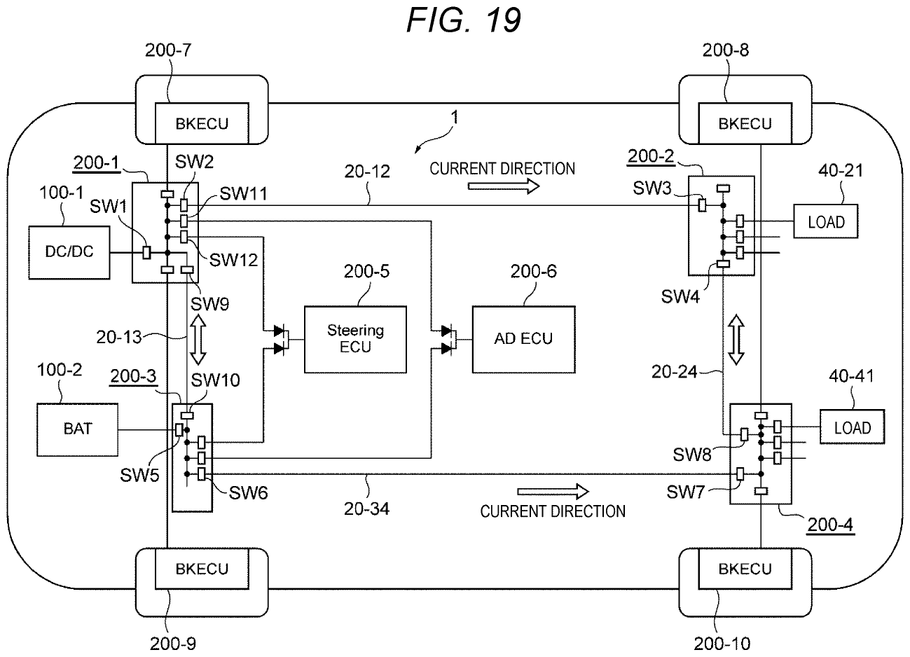

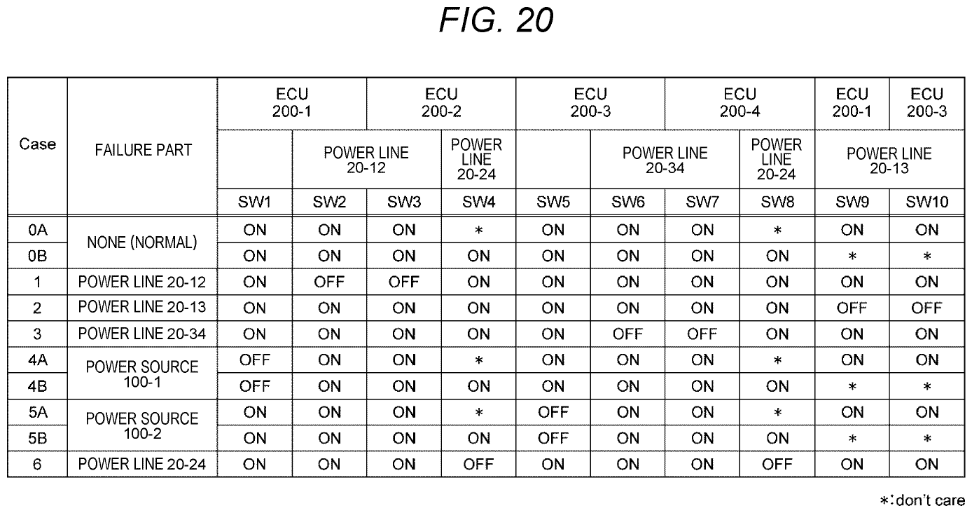

FIG. 19 illustrates an example in which the ECU 200-2 and the ECU 200-4 are further connected by the power line 20-24 via the switches SW 4 and SW 8 with respect to the configuration of FIG. 16. An operation example of the switch SW of the present example is illustrated in FIG. 20. Note that FIG. 20 is obtained by adding control of the switches SW 4 and SW 8 provided at both ends of the power line 20-24 in addition to the operation example illustrated in FIG. 17.

When there is no failure part (normal), all the switches do not need to be turned OFF, and power is supplied to all the loads, but even in this case, there are two options of Cases OA and OB. As illustrated in Case OA, when the switches SW 9 and SW 10 are turned ON and the ECU 200-1 and the ECU 200-3 are connected via the power line 20-13, the switches SW 4 and SW 8 connected to the power line 20-24 connecting the ECU 200-2 and the ECU 200-4 may be turned ON or OFF. Furthermore, as illustrated in Case OB, when the switches SW 4 and SW 8 are turned ON and the ECU 200-2 and the ECU 200-4 are connected via the power line 20-24, the switches SW 9 and SW 10 connected to the power line 20-13 connecting the ECU 200-1 and the ECU 200-3 may be turned ON or OFF. In the table, “*” represents don't care, that is, may be ON or OFF.

The Cases 1 to 3 are the same as each case illustrated in FIG. 17, and the description thereof will be omitted.

When a failure occurs in the power source 100-1, there are two options of Cases 4A and 4B. As illustrated in Case 4A, when the switches SW 9 and SW 10 are turned ON and the ECU 200-1 and the ECU 200-3 are connected via the power line 20-13, the switches SW 4 and SW 8 connected to the power line 20-24 connecting the ECU 200-2 and the ECU 200-4 may be turned ON or OFF. Furthermore, as illustrated in Case 4B, when the switches SW 4 and SW 8 are turned ON and the ECU 200-2 and the ECU 200-4 are connected via the power line 20-24, the switches SW 9 and SW 10 connected to the power line 20-13 connecting the ECU 200-1 and the ECU 200-3 may be turned ON or OFF. At this time, power is supplied to the entire in-vehicle power supply network by the output of the power source 100-2.

When a failure occurs in the power source 100-2, there are two options of Cases 5A and 5B. As illustrated in Case 5A, when the switches SW 9 and SW 10 are turned ON and the ECU 200-1 and the ECU 200-3 are connected via the power line 20-13, the switches SW 4 and SW 8 connected to the power line 20-24 connecting the ECU 200-2 and the ECU 200-4 may be turned ON or OFF. Furthermore, as illustrated in Case 5B, when the switches SW 4 and SW 8 are turned ON and the ECU 200-2 and the ECU 200-4 are connected via the power line 20-24, the switches SW 9 and SW 10 connected to the power line 20-13 connecting the ECU 200-1 and the ECU 200-3 may be turned ON or OFF. At this time, power is supplied to the entire in-vehicle power supply network by the output of the power source 100-1.

Case 6 is a case where a failure occurs in the power line 20-24. The failure is detected according to the principle of the present invention, and the switches SW 4 and SW 8 are turned OFF and the power line 20-24 is disconnected. Power is supplied to the ECU 200-2 and the ECU 200-4 via power lines 20-12 and 20-34, respectively.

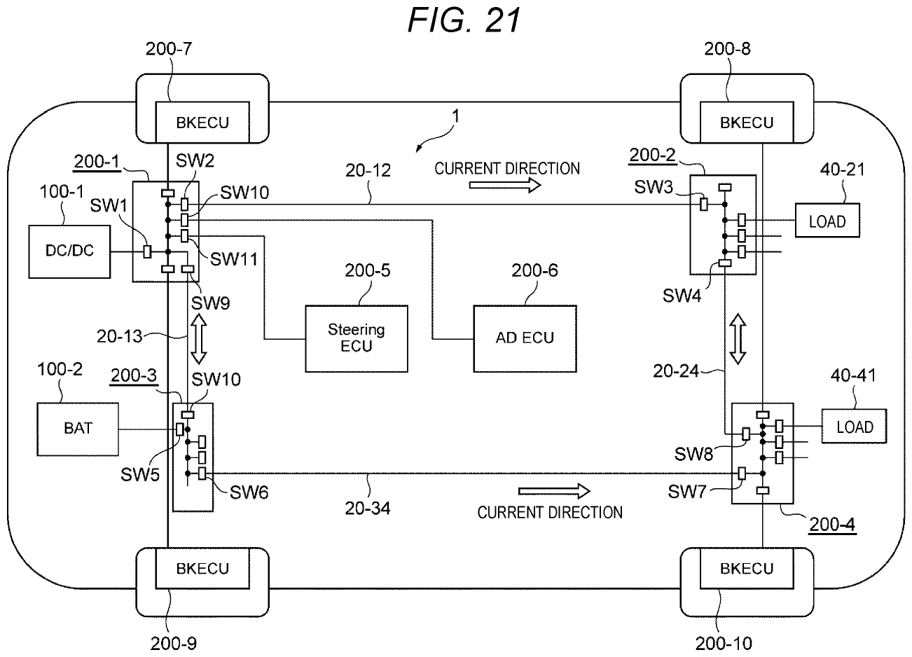

As described above, by connecting the ECU 200-2 and the ECU 200-4 by the power line 20-24 via the switches SW 4 and SW 8, it is possible to continue power supply to the load even if a failure occurs in any of the power line 20-12, the power line 20-13, and the power line 20-34, and thus the diode OR for supplying power from the power source 100-2 to the steering ECU 200-5 and the automatic driving ECU 200-6 can be omitted as illustrated in FIG. 21.

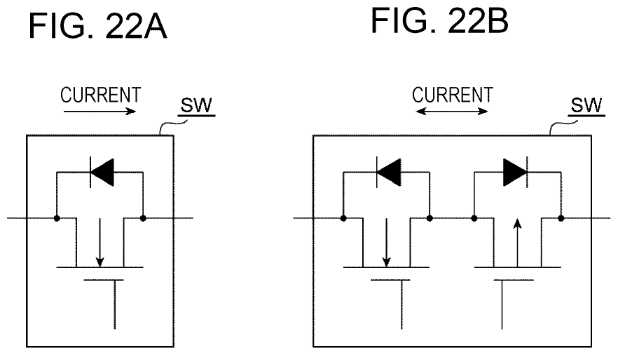

Note that, in the [Seventh example], since the current flows bidirectionally only through the wiring to the power source 100-2 and the power line 20-13, in a case where the switches SW 5, SW 9, and SW 10 are realized by semiconductor switches, elements having opposite polarities need to be connected as illustrated in FIG. 22(b) so that the bidirectional current can be controlled. Since current flows in a single direction through the other power lines 20-12 and 20-34, the other SWs may be elements of a single polarity as illustrated in FIG. 22(a). In addition, in the [Eighth example], since the current flows bidirectionally through the wiring to the power source 100-2 and all the power lines 20-12, 20-13, 20-34, and 20-24, in a case where SW 2 to SW 10 are realized by semiconductor switches, elements having opposite polarities need to be connected as illustrated in FIG. 22(b) so that the bidirectional current can be controlled.

According to the examples of the present invention described above, the following operational effects are obtained.

(1) An in-vehicle power supply network according to the present invention is an in-vehicle power supply network that supplies power to a load installed in a vehicle via a plurality of nodes in the vehicle, in which the plurality of nodes includes a first node that feeds power and a second node that receives the power fed out from the first node, the first and second nodes are connected by a power line over which the power is supplied and a signal line through which information relating the power is transmitted, each of the first and second nodes includes a current measurement unit that measures a current value entering and exiting the own node via the power line, a current input/output unit that inputs and outputs a current proportionate to the current value between the signal line and the own node, and a potential measurement unit that measures a potential of the signal line, the signal line is terminated at a terminal potential via a resistor, and when the potential of the signal line is different from the terminal potential, it is diagnosed that an abnormality has occurred somewhere in the in-vehicle power supply network.

The occurrence of a failure can be quickly detected in an in-vehicle power supply network using a direct current by adopting the above configuration.

(2) The current measurement unit and the current input/output unit are configured by an operational amplifier. As a result, even if the current output from the ECU is weak, the current can be reliably detected by amplification.

(3) The terminal potential and the resistor are configured by Thevenin termination. As a result, it is not necessary to provide a power supply separately from the positive power supply voltage for the terminal potential, and miniaturization and cost suppression of the entire system can be expected.

(4) The potential measurement unit of each of the first and second nodes measures the potential of the signal line on the own node side than the position where the signal line is terminated with the terminal potential. As a result, each node can determine at which position of the signal line a failure has occurred.

(5) The first and second nodes exchange the measured potentials of the signal lines with each other via the network. As a result, each node can specify the cause of the failure by comparing the potential measured by the node itself with the received potential.

(6) When the exchanged potentials of the signal lines of the first and second nodes are different, it is diagnosed that any of the signal line, the current measurement unit, and the current input/output unit is abnormal. By adopting the above configuration (5), it is possible to specifically perform such diagnosis.

(7) The first and second nodes encode the measured potential of the signal line, and superimpose and transmit the potential on the signal line. By adopting the multiplexed network communication as described in the third example, such efficient information transmission can be performed.

(8) The node is an electronic control unit, which electronic control unit includes a current measurement unit, a current input/output unit, a first open/close device that opens and closes a current to a power line connected to the electronic control unit, a second open/close device that opens and closes a current to a load connected to the electronic control unit, and a control circuit, and the control circuit controls the first and second open/close devices. This makes it possible to immediately cut off the power line or the load current supply path that is diagnosed that a failure has occurred, and to quickly protect the power supply network.

(9) The control circuit is supplied with power from a plurality of paths. As a result, even if the power supply is cut off from some of the power supplies, the power supply to the control circuit can be continued by appropriately controlling the switching circuit.

(10) When it is diagnosed that an abnormality has occurred in the signal line, the control circuit of the electronic control unit to which the signal line is connected opens the first open/close device of the electronic control unit. This makes it possible, as in (9), to quickly protect the power supply network after finding a failure.

Note that the present invention is not limited to the above examples, and various modifications are possible. For example, the above-described examples have been described in detail in order to describe the present invention in an easy-to-understand manner, and the present invention is not necessarily limited to an aspect including all the described configurations. Furthermore, a part of the configuration of one example can be replaced with the configuration of another example. Moreover, the configuration of another example can be added to the configuration of a certain example. In addition, a part of the configuration of each example can be deleted, or another configuration can be added or replaced.

### REFERENCE SIGNS LIST

20 power line
21 sensing line
40 load
100 power source
200 node (electronic control unit: ECU)
201, 203 current measurement unit
202, 204 current input/output unit
210 control function (control circuit)

1. An in-vehicle power supply network that supplies power to a load installed in a vehicle via a plurality of nodes in the vehicle, wherein
the plurality of nodes includes a first node that feeds power and a second node that receives the power fed out from the first node,
the first and second nodes are connected by a power line over which the power is supplied and a signal line through which information relating the power is transmitted,
each of the first and second nodes includes a current measurement unit that measures a current value entering and exiting the own node via the power line, a current input/output unit that inputs and outputs a current proportionate to the current value between the signal line and the own node, and a potential measurement unit that measures a potential of the signal line, and
the signal line is terminated at a terminal potential via a resistor, and when the potential of the signal line is different from the terminal potential, diagnosis is made that an abnormality has occurred somewhere in the in-vehicle power supply network.

2. The in-vehicle power supply network according to claim 1, wherein
the current measurement unit and the current input/output unit are configured by an operational amplifier.

3. The in-vehicle power supply network according to claim 1, wherein
the terminal potential and the resistor are configured by a Thevenin termination.

4. The in-vehicle power supply network according to claim 1, wherein
the potential measurement unit of each of the first and second nodes measures a potential of the signal line on an own node side than a position where the signal line is terminated with the terminal potential.

5. The in-vehicle power supply network according to claim 4, wherein
the first and second nodes exchange potentials of the signal lines measured with each other via a network.

6. The in-vehicle power supply network according to claim 5, wherein
when the exchanged potentials of the signal lines of the first and second nodes are different, diagnosis is made that any of the signal line, the current measurement unit, and the current input/output unit is abnormal.

7. The in-vehicle power supply network according to claim 5, wherein
the first and second nodes encode the measured potentials of the signal lines and superimpose and transmit the potentials on the signal lines.

8. The in-vehicle power supply network according to claim 1, wherein
the node is an electronic control unit,
the electronic control unit includes the current measurement unit, the current input/output unit, a first open/close device that opens and closes a current to the power line connected to the electronic control unit, a second open/close device that opens and closes a current to a load connected to the electronic control unit, and a control circuit, and
the control circuit controls the first and second open/close devices.

9. The in-vehicle power supply network according to claim 8, wherein
the control circuit is supplied with power from a plurality of paths.

10. The in-vehicle power supply network according to claim 8, wherein
when diagnosis is made that an abnormality has occurred in the signal line, the control circuit of the electronic control unit to which the signal line is connected opens the first open/close device of the electronic control unit.
